(19) United States
(12) Patent Application Publication
(10) Pub. No.: US 2017/0186795 A1
(43) Pub. Date: Jun. 29, 2017

(54) IMAGE SENSOR AND MANUFACTURING METHOD THEREOF

(71) Applicant: UNITED MICROELECTRONICS CORP., Hsin-Chu City (TW)

(72) Inventors: Hsin-Ting Tsai, Hsinchu City (TW); Cheng-Hung Yu, Taoyuan City (TW); Chin-Kuang Liu, Hsinchu City (TW); Ming-Hsin Lee, Taoyuan City (TW); Hung-Sheng Chang, Hsinchu County (TW)

(21) Appl. No.: 14/993,094

(22) Filed: Jan. 12, 2016

(30) Foreign Application Priority Data
Dec. 28, 2015 (CN) 201511000592.8

(51) Int. Cl. H01L 27/146; G02B 3/00

(52) U.S. Cl. CPC H01L 27/14627; G02B 3/0062; G02B 3/0031; H01L 27/14621; H01L 27/14685

(57) ABSTRACT

An image sensor is provided in the present invention. The image sensor includes a continuous microlens including a plurality of top sub lenses connected with one another and a plurality of bottom sub lenses disposed corresponding to the top sub lenses. The continuous microlens maybe used to enhance quantum efficiency. The top sub lens and the bottom sub lens condense light by two steps within a shorter distance and make the light focused on a sensing element, and the continuous microlens may be applied without the limitation about the size of the pixel region accordingly. Additionally, the sensitivity and the uniformity thereof may be enhanced because of the shorter distance between the bottom sub lens and the sensing element. A transmittance of a color filter layer disposed corresponding to the bottom sub lens may also be enhanced.

### BACKGROUND OF THE INVENTION

1. Field of the Invention

The present invention relates to an image sensor and a manufacturing method thereof, and more particularly, to an image sensor including a continuous microlens and a manufacturing method thereof.

2. Description of the Prior Art

With the development of computer and communications industries, demand for high-efficiency image sensor has been increased. Such image sensors are used in various fields, such as digital cameras, camcorders, personal communications systems, game components, monitors, medical micro camera, robots, etc.

In the conventional image sensor, microlenses disposed in pixel regions are separated from one another, and each of the microlenses is configured to condense light for each of the pixel regions. The microlenses separated from one another may be manufactured easily and may be applied to pixel regions within a wider size range. However, the quantum efficiency of the microlenses separated from one another is relatively low and the performance of the image sensor may be influenced accordingly. Therefore, a continuous microlens is applied recently for enhancing the quantum efficiency. Unfortunately, for forming the continuous microlens including a plurality of microlenses connected with one another and corresponding to pixel regions, the continuous microlens will be limited to the manufacturing process and cannot be formed with a specific height when each of the pixel regions is relatively large (for example, about larger than 3 micrometers). Therefore, the curvature radius of the microlens corresponding to the pixel region will be too large and the incident light cannot be focused on the photodiode effectively. In other words, the continuous microlens in this condition cannot be applied in the image sensor with a larger pixel region, and the method of enhancing the performance of the image sensor by the continuous microlens is limited to specific designs.

### SUMMARY OF THE INVENTION

It is one of the objectives of the present invention to provide an image sensor and a manufacturing method thereof. A top sub lens of a continuous microlens and another bottom sub lens are used together for condensing light by two steps within a shorter distance and make the light focused on a sensing element. Accordingly, the application of the continuous microlens will not be limited to the size of the pixel region, and the quantum efficiency may be enhanced by the continuous microlens. Additionally, the sensitivity and the uniformity thereof may be enhanced because of the shorter distance between the bottom sub lens and the sensing element, and a transmittance of a color filter layer disposed corresponding to the bottom sub lens may also be enhanced.

An image senor is provided by an embodiment of the present invention. The image sensor includes a substrate, a continuous microlens, and a plurality of bottom sub lenses. The substrate includes a plurality of pixel regions and a plurality of sensing elements. Each of the sensing elements is disposed in one of the pixel regions. The continuous microlens is disposed on the substrate. The continuous microlens includes a plurality of top sub lenses, the top sub lenses are connected with one another, and each of the top sub lenses is disposed corresponding to one of the sensing elements. The bottom sub lenses are disposed between the continuous microlens and the substrate. Each of the bottom sub lenses is disposed corresponding to one of the top sub lenses and one of the sensing elements. The bottom sub lenses are separated from one another, and the bottom sub lens is smaller than the top sub lens.

A manufacturing method of an image sensor is provided by an embodiment of the present invention. The manufacturing method includes the following steps. A substrate is provided. The substrate includes a plurality of pixel regions and a plurality of sensing elements, and each of the sensing elements is disposed in one of the pixel regions. A plurality of bottom sub lenses are formed on the substrate. Each of the bottom sub lenses is formed corresponding to one of the sensing elements, and the bottom sub lenses are separated from one another. A continuous microlens is formed above the bottom sub lenses. The continuous microlens includes a plurality of top sub lenses. The top sub lenses are connected with one another. Each of the top sub lenses is formed corresponding to one of the sensing elements and one of the bottom sub lenses, and the bottom sub lens is smaller than the top sub lens.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating an image sensor according to a first embodiment of the present invention.

FIG. 2 is a schematic cross-sectional diagram taken along a line A-A′ in FIG. 1.

FIG. 3 is a schematic drawing illustrating relative sizes of a top sub lens, a bottom sub lens, and a pixel region of the image sensor in the first embodiment of the present invention.

FIGS. 4-6 are schematic drawings illustrating a manufacturing method of bottom sub lenses in the image sensor according to the first embodiment of the present invention, wherein

FIG. 5 is a schematic drawing in a step subsequent to FIG. 4, and

FIG. 6 is a schematic drawing in a step subsequent to FIG. 5.

FIGS. 7-9 are schematic drawings illustrating a manufacturing method of a continuous microlens in the image sensor according to the first embodiment of the present invention, wherein

FIG. 8 is a schematic drawing in a step subsequent to FIG. 7, and

FIG. 9 is a schematic drawing in a step subsequent to FIG. 8.

FIG. 10 is a schematic drawing illustrating a gray tone mask used in the manufacturing method of the image sensor according to the first embodiment of the present invention.

FIG. 11 is a schematic drawing illustrating an image sensor according to a second embodiment of the present invention.

### DETAILED DESCRIPTION

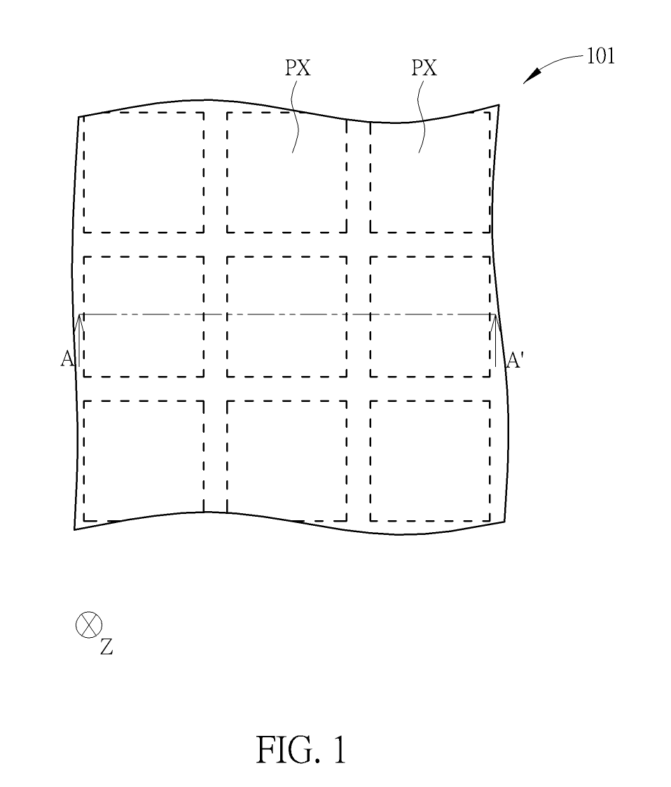

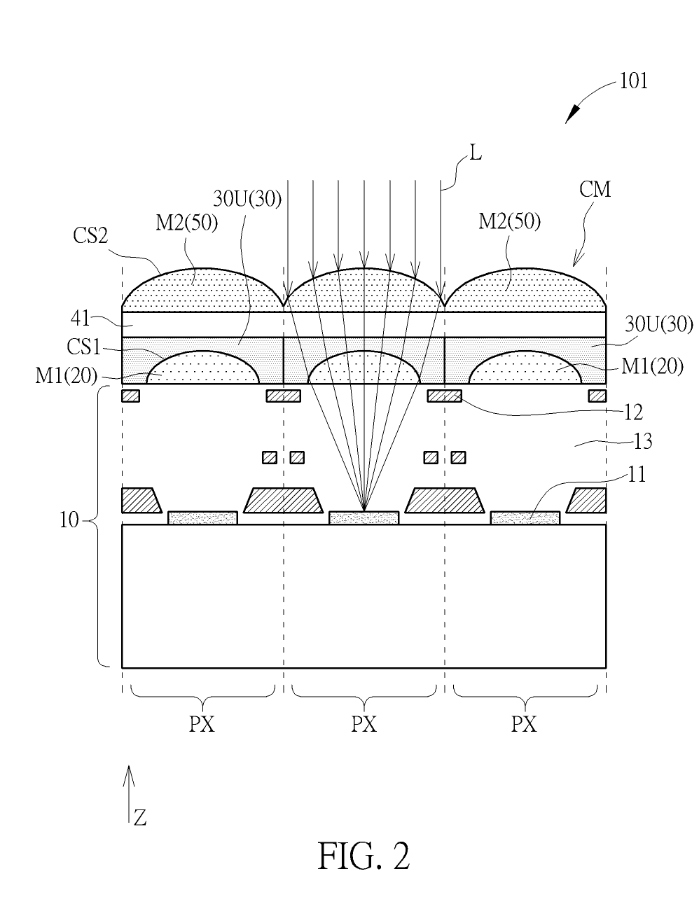

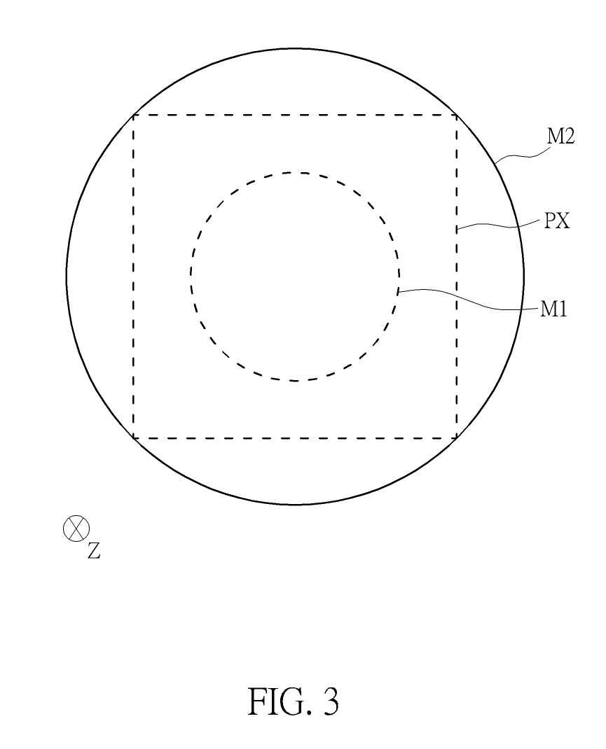

Please refer to FIGS. 1-3. FIG. 1 is a schematic drawing illustrating an image sensor according to a first embodiment of the present invention. FIG. 2 is a schematic cross-sectional diagram taken along a line A-A′ in FIG. 1. FIG. 3 is a schematic drawing illustrating relative sizes of a top sub lens, a bottom sub lens, and a pixel region of the image sensor in this embodiment. As shown in FIG. 1 and FIG. 2, an image sensor 101 is provided in this embodiment. The image sensor 101 includes a substrate 10, a continuous microlens CM, and a plurality of bottom sub lenses M1. The substrate 10 includes a plurality of pixel regions PX and a plurality of sensing elements 11. The pixel regions PX are aligned in an array configuration, and each of the sensing elements 11 is disposed in one of the pixel regions PX. In this embodiment, the substrate 10 may include a silicon substrate, a silicon-containing substrate, a III-V group-on-silicon substrate such as a GaN-on-silicon substrate, a graphene-on-silicon substrate, or a silicon-on-insulator (SOI) substrate. Apart from the sensing elements 11 mentioned above, an isolation structure 12 and a dielectric layer 13 may also be disposed in the substrate 10. The isolation structure 12 may be used to isolate the sensing elements 11 in the pixel regions PX from one another and to avoid noise between the sensing elements 11. The sensing element 11 maybe a sensing region such as a photodiode of a sensing device, and the sensing device may include a charge-coupled device (CCD), a complementary metal-oxide-semiconductor (CMOS) image sensor (CIS) device, an active-pixel sensor (API) device, a passive-pixel sensor (PPI) device, or other appropriate sensing device. In addition, inter connection structures (not shown) may also be disposed in the substrate 10 according to the design consideration, but not limited thereto.

In this embodiment, the continuous microlens CM is disposed on the substrate 10, and the continuous microlens CM includes a plurality of top sub lenses M2. The top sub lenses M2 are connected with one another, and each of the top sub lenses M2 is disposed corresponding to one of the sensing elements 11. The bottom sub lenses M1 are disposed between the continuous microlens CM and the substrate 10. Each of the bottom sub lenses M1 is disposed corresponding to one of the top sub lenses M2 and one of the sensing elements 11. The bottom sub lenses M1 are separated from one another, and the bottom sub lens M1 is smaller than the top sub lens M2. Specifically, in the image sensor 101, one of the top sub lenses M2 in the continuous microlens CM, one of the bottom sub lenses M1 and the sensing element 11 in a corresponding pixel region PX overlap one another in a vertical projection direction Z preferably. A projection area of the top sub lens M2 in the vertical projection direction Z is larger than a projection area of the bottom sub lens M1 in the vertical projection direction Z. For example, as shown in FIG. 3, the projection area of the top sub lens M2 in the vertical projection direction Z may be about 1.4 times of an area of the pixel region PX, and the projection area of the bottom sub lens M1 in the vertical projection direction Z may be about 55% to 75% of the area of the pixel region PX, but not limited thereto. The area of the pixel region PX mentioned above may be an area of an aperture defined by the isolation structure 12, but not limited thereto. In this embodiment, the shape of the top sub lens M2 and the shape of the bottom sub lens M1 in the vertical projection direction Z may be a circle respectively, but not limited thereto. In other embodiments of the present invention, the shape of the top sub lens M2 and/or the shape of the bottom sub lens M1 in the vertical projection direction Z may be further modified according to other design considerations. Additionally, the materials of the top sub lenses M2 and the bottom sub lenses M1 may include an organic material or other suitable transparent materials.

As shown in FIG. 2, in this embodiment, each of the top sub lenses M2 and each of the bottom sub lenses M1 are lenses cambering upward, and a cambering direction of the bottom sub lens M2 is the same with a cambering direction of the top sub-lens M1. In addition, a curvature radius of the bottom sub lens M1 is smaller than a curvature radius of the top sub lens M2, and incident light L may be further condensed by the bottom sub lens M1 after passing through the top sub lens M2. In other words, the top sub lens M2 of the continuous microlens CM and the bottom sub lens M2 with a relatively shorter curvature radius are used together for condensing light by two steps within a relatively shorter distance and making the incident light L focused on the sensing element 11 within a specific and limited distance. According to the design of the present invention, the bottom sub lens M1 with the shorter curvature radius may be used to further condense light when the curvature radius of each of the top sub lenses M2 becomes larger because the continuous microlens CM has to be formed corresponding to a larger pixel region PX, and the application of the continuous microlens CM in the design of the present invention will not be limited to the size of the corresponding pixel region PX. The purpose of enhancing the quantum efficiency by using the continuous microlens CM may be achieved accordingly.

As shown in FIG. 2, the image sensor 101 in this embodiment may further include a color filter layer 30 and a first planar layer 41. The color filter layer 30 and the first planar layer 41 are disposed between the continuous microlens CM and the bottom sub lenses M1. The first planar layer 41 disposed on the color filter layer 30, and the continuous microlens CM is disposed on the first planar layer 41. In this embodiment, the color filter layer 30 directly contacts and covers a cambered surface of each of the bottom sub lenses M1, such as a first cambered surface CS1 shown in FIG. 2. A thickness of a part of the color filter layer 30 corresponding to an apex of the first cambered surface CS1 will be less than thicknesses of the other parts of the color filter layer 30, and the transmittance of the color filter layer 30 in this design may be enhanced accordingly. Additionally, the color filter layer 30 may include a plurality of color filter units 30U disposed corresponding to the pixel regions PX respectively. The color filter units 30U may include color filter units for different colors, such as red color filter units, green color filter units, and blue color filter units, but not limited thereto. In the image sensor 101 of this embodiment, the distance between the bottom sub lens M1 and the sensing element 11 may become shorter because the bottom sub lenses M1 are disposed under the color filter layer 30, and the sensitivity of the image sensor 11 and the uniformity of the sensitivity may be enhanced accordingly.

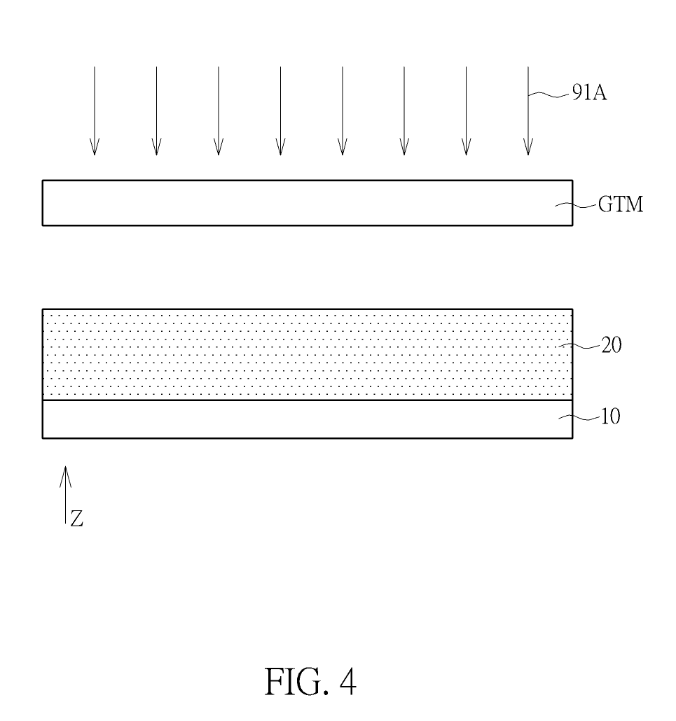

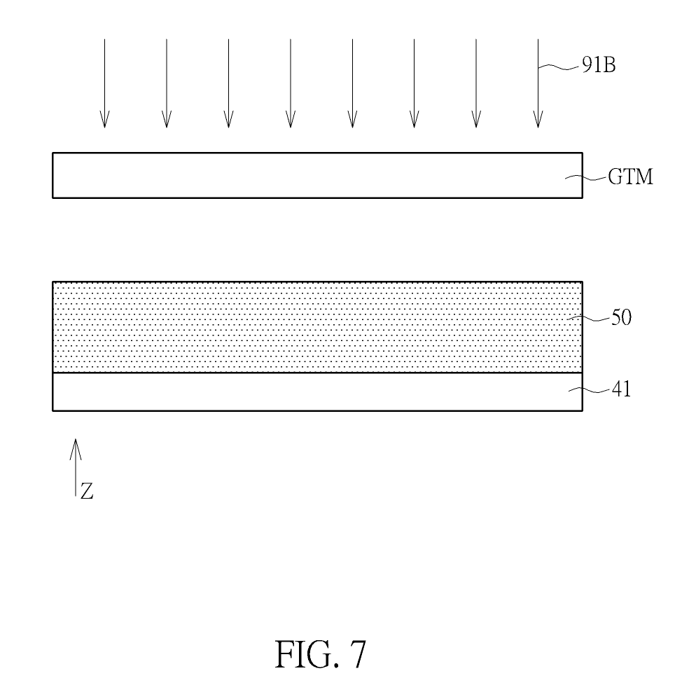

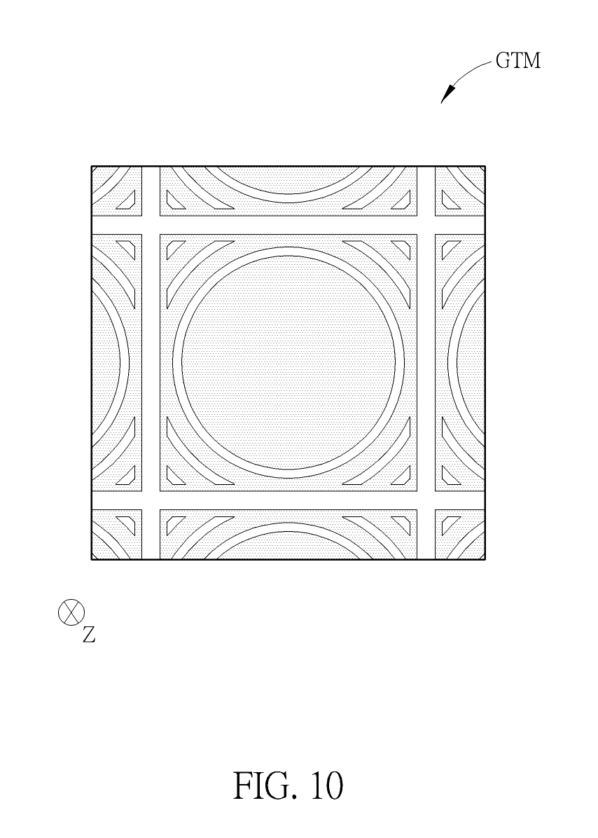

Please refer to FIGS. 4-10 and FIG. 2. FIGS. 4-6 are schematic drawings illustrating a manufacturing method of the bottom sub lenses M1 in the image sensor 101 of this embodiment. FIGS. 7-9 are schematic drawings illustrating a manufacturing method of the continuous microlens CM in the image sensor 101 of this embodiment. FIG. 10 is a schematic drawing illustrating a gray tone mask used in the manufacturing method of the image sensor 101 in this embodiment. As shown in FIG. 2, a manufacturing method of the image sensor 101 is provided in this embodiment. The manufacturing method includes the following steps. First of all, the substrate 10 is provided. The substrate 10 includes a plurality of the pixel regions PX and a plurality of the sensing elements 11. Each of the sensing elements 11 is disposed in one of the pixel regions PX. A plurality of the bottom sub lenses M1 are then formed on the substrate 10. Each of the bottom sub lenses M1 is formed corresponding to one of the sensing elements 11, and the bottom sub lenses M1 are separated from one another. The continuous microlens CM is then formed above the bottom sub lenses M1. The continuous microlens CM includes a plurality of the top sub lenses M2. The top sub lenses M2 are connected with one another. Each of the top sub lenses M2 is formed corresponding to one of the sensing elements 11 and one of the bottom sub lenses M1, and the bottom sub lens M1 is smaller than the top sub lens M2.

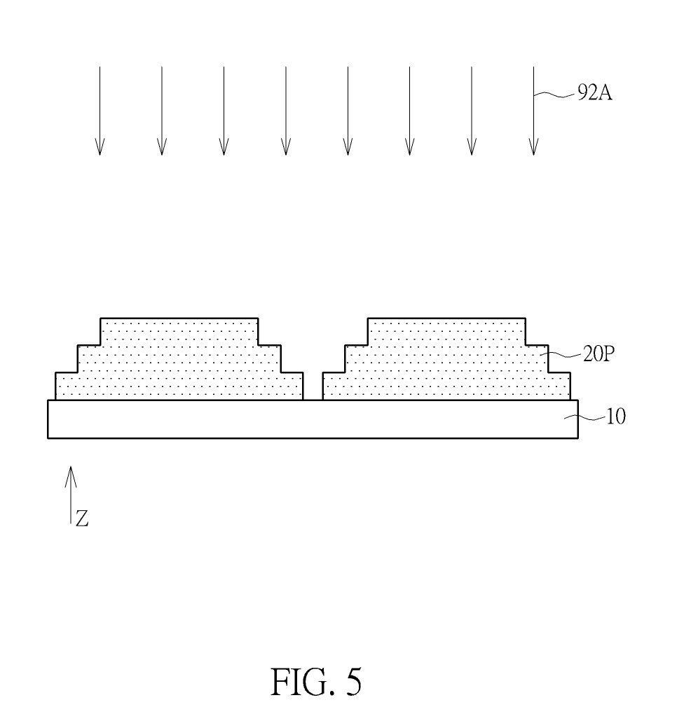

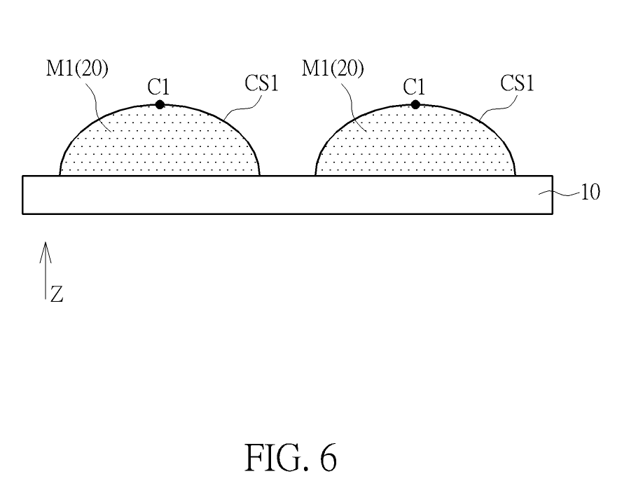

The method of forming the bottom sub lenses M1 may include the following steps. As shown in FIG. 4, a first photosensitive material layer 20 is formed on the substrate 10. The first photosensitive material layer 20 may include an organic material capable of being photopatterned or other suitable materials capable of being photopatterned. Subsequently, a first photolithographic process is performed with a gray tone mask GTM. For example, the first photolithographic process may include a first exposure process 91A and a develop process, and the gray tone mask may be used in the first exposure process 91A. As shown in FIG. 4 and FIG. 5, a plurality of first patterns 20P may be formed after the first exposure process 91A and the develop process are performed to the first photosensitive material layer 20. By using the gray tone mask GTM (as shown in FIG. 10) in this embodiment, the transmittances at specific regions of the gray tone mask GTM may be different for the light source used in the exposure process because of the slits or the material design used in the gray tone mask GTM, and the first patterns 20P may have a ladder shaped edge with gradual thickness variations. As shown in FIG. 5 and FIG. 6, a first thermal treatment 92A is performed to the first patterns 20P for forming the bottom sub lenses M1 separated from one another. The bottom sub lenses M1 may be formed corresponding to the size of different pixel regions and may be reworkable because the bottom sub lenses M1 are formed by performing the first photolithographic process to the first photosensitive material layer 20 in this embodiment. In addition, the first thermal treatment 92A may be a multiple thermal treatment preferably, such as a triple thermal treatment, so as to ensure that the shape of the bottom sub lenses M1 meet the demand and the bottom sub lenses M1 are completely cured for avoiding deformation in sequent high temperature processes of forming material layers such as the color filter layer or the planar layer. For example, the triple thermal treatment mentioned above may include modifying the shape of the first patterns 20P and then curing the first patterns 20P by three different temperature settings (such as 160° C., 190° C., and 220° C.) and corresponding treatment times respectively, but not limited thereto.

As shown in FIG. 2, the manufacturing method in this embodiment may further include forming the color filter layer 30 and the first planar layer 41 above the bottom sub lenses M1. The color filter layer 30 directly contacts and covers the first cambered surface CS1 of each of the bottom sub lenses M1, and the first planar layer 41 is disposed on the color filter layer 30. The continuous microlens CM including a plurality of the top sub lenses M2 connected with one another is then formed on the first planar layer 41. In this embodiment, the method of forming the top sub lenses M2 in the continuous microlens CM may include the following steps. As shown in FIG. 2 and FIG. 7, a second photosensitive material layer 50 is formed on the substrate 10, and the second photosensitive material layer 50 may also be regarded as being formed on the first planar layer 41. The second photosensitive material layer 50 may also include an organic material capable of being photopatterned or other suitable materials capable of being photopatterned. Subsequently, a second photolithographic process is performed with the gray tone mask GTM. For example, the second photolithographic process may include a second exposure process 91B and a develop process, and the gray tone mask may be used in the second exposure process 91B. This is worth noting that the bottom sub lenses M1 and the top sub lenses M2 in this embodiment may be formed by the same gray tone mask GTM used in the first exposure process and the second exposure process 91B with different exposure conditions, but not limited thereto. Accordingly, the amount of the required photomasks may be reduced and the alignment shift between the bottom sub lens M1 and the top sub lens M2 may be improved. In other embodiments of the present invention, the bottom sub lenses M1 and the top sub lenses M2 may also be formed by different photomasks according to other design considerations.

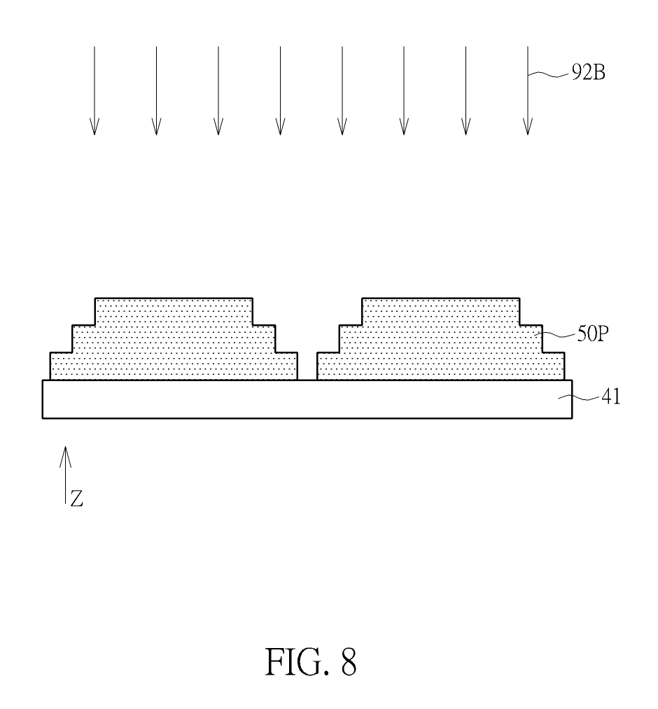

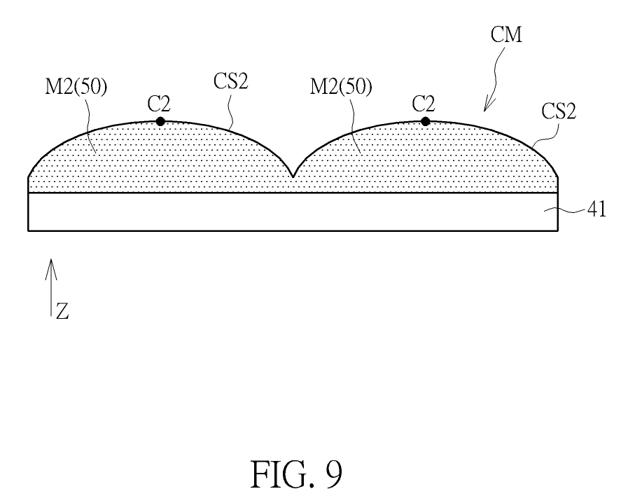

As shown in FIG. 7 and FIG. 8, a plurality of second patterns 50P may be formed after the second exposure process 91B and the develop process are performed to the second photosensitive material layer 50. By using the same gray tone mask GTM, the second patterns 50P may also have a ladder shaped edge with gradual thickness variations. As shown in FIG. 8 and FIG. 9, a second thermal treatment 92B is then performed to the second patterns 50P. The second thermal treatment 92B may also include a multiple thermal treatment, and the top sub lenses M2 may be formed on the first planar layer 41 and connected with one another for forming the continuous microlens CM by adjusting the temperature and the treatment time of the second thermal treatment 92B. The difference between the first thermal treatment for forming the bottom sub lenses mentioned above and the second thermal treatment 92B is that the time of the first thermal treatment step for adjusting the shape may be relatively longer in the second thermal treatment 92B, and the second patterns 50 may reflow effectively for being connected with one another and forming the continuous microlens CM, but not limited thereto. Additionally, as shown in FIG. 2, FIG. 6, and FIG. 9, a first apex C1 on the first cambered surface CS1 of the bottom sub lens M1 and a second apex C2 on a second cambered surface CS2 of the top sub lens M2 may overlap each other in the vertical projection direction Z so as to form the required light condensing effect, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

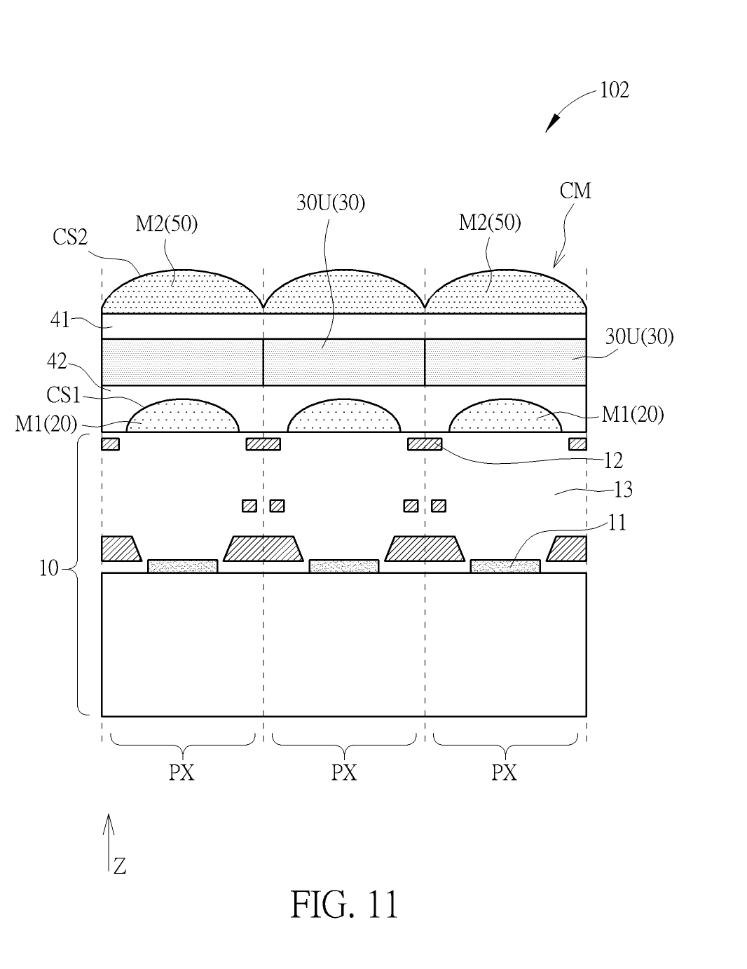

Please refer to FIG. 11. FIG. 11 is a schematic drawing illustrating an image sensor 102 according to a second embodiment of the present invention. As shown in FIG. 11, the difference between the image senor 102 of this embodiment and the image senor of the first embodiment mentioned above is that the image senor 102 may further include a second planar layer 42 disposed between the color filter layer 30 and the bottom sub lenses M1, and the second planar layer 42 directly contacts and covers the first cambered surface CS1 of each of the bottom sub lenses M1. In other words, the manufacturing method of the image sensor 102 in this embodiment may further include forming the second planar layer 42 on the bottom sub lenses M1, and the color filter layer 30 is formed on the second planar layer 42. Therefore, the thickness distribution of the color filter layer 30 may be more uniform relatively for enhancing the color filtering performance of the color filter layer 30, and the sensitivity of the image sensor 102 may also be improved.

To summarize the above descriptions, in the image sensor of the present invention, the top sub lens of the continuous microlens and the corresponding bottom sub lens are used together for condensing light by two steps and making the incident light focused on the sensing element within a relatively shorter distance. According to the design of the present invention, the application of the continuous microlens will not be limited to the size of the pixel region, and the quantum efficiency may be enhanced by the continuous microlens. Additionally, the sensitivity and the uniformity thereof may be enhanced because of the shorter distance between the bottom sub lens and the sensing element, and the transmittance of the color filter layer may also be enhanced when the color filter layer directly contacts and covers the bottom sub lenses. In the manufacturing method, organic photosensitive material layers may be used to form the top sub lenses of the continuous microlens connected with one another and the bottomed sub lenses separated from one another by performing the exposure processes in different exposure conditions with the same gray tone mask. The shapes and the curing conditions of the top sub lenses and/or the bottom sub lenses may be ensured by adjusting the multiple thermal treatments.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An image sensor, comprising:
a substrate comprising a plurality of pixel regions and a plurality of sensing elements, wherein each of the sensing elements is disposed in one of the pixel regions;
a continuous microlens, disposed on the substrate, wherein the continuous microlens comprises a plurality of top sub lenses, the top sub lenses are connected with one another, and each of the top sub lenses is disposed corresponding to one of the sensing elements; and
a plurality of bottom sub lenses, disposed between the continuous microlens and the substrate, wherein each of the bottom sub lenses is disposed corresponding to one of the top sub lenses and one of the sensing elements, the bottom sub lenses are separated from one another, and the bottom sub lens is smaller than the top sub lens.

2. The image sensor of claim 1, wherein a curvature radius of the bottom sub lens is smaller than a curvature radius of the top sub lens.

3. The image sensor of claim 1, wherein a cambering direction of the bottom sub lens is the same with a cambering direction of the top sub-lens.

4. The image sensor of claim 1, further comprising a first planar layer disposed between the continuous microlens and the bottom sub lenses, wherein the continuous microlens is disposed on the first planar layer.

5. The image sensor of claim 1, further comprising a color filter layer disposed between the continuous microlens and the bottom sub lenses.

6. The image sensor of claim 5, wherein the color filter layer directly contacts and covers a cambered surface of each of the bottom sub lenses.

7. The image sensor of claim 5, further comprising a second planar layer disposed between the color filter layer and the bottom sub lenses, wherein the second planar layer covers a cambered surface of each of the bottom sub lenses.

8. The image sensor of claim 1, wherein the top sub lenses and the bottom sub lenses comprise organic material.

9. A manufacturing method of an image sensor, comprising:
providing a substrate, wherein the substrate comprises a plurality of pixel regions and a plurality of sensing elements, and each of the sensing elements is disposed in one of the pixel regions;
forming a plurality of bottom sub lenses on the substrate, wherein each of the bottom sub lenses is formed corresponding to one of the sensing elements, and the bottom sub lenses are separated from one another;
forming a continuous microlens above the bottom sub lenses, wherein the continuous microlens comprises a plurality of top sub lenses, the top sub lenses are connected with one another, each of the top sub lenses is formed corresponding to one of the sensing elements and one of the bottom sub lenses, and the bottom sub lens is smaller than the top sub lens.

10. The manufacturing method of claim 9, wherein the step of forming the bottom sub lenses comprises:
forming a first photosensitive material layer on the substrate; and
performing a first photolithographic process with a gray tone mask to form a plurality of first patterns.

11. The manufacturing method of claim 10, wherein the step of forming the bottom sub lenses further comprises:
performing a first thermal treatment to the first patterns to form the bottom sub lenses separated from one another.

12. The manufacturing method of claim 11, wherein the first thermal treatment comprises a multiple thermal treatment.

13. The manufacturing method of claim 10, wherein the step of forming the top sub lenses comprises:
forming a second photosensitive material layer on the substrate; and
performing a second photolithographic process with the gray tone mask to form a plurality of second patterns.

14. The manufacturing method of claim 13, wherein the step of forming the top sub lenses further comprises:
performing a second thermal treatment to the second patterns to form the top sub lenses connected with one another.

15. The manufacturing method of claim 9, wherein a curvature radius of the bottom sub lens is smaller than a curvature radius of the top sub lens.

16. The manufacturing method of claim 9, wherein a cambering direction of the bottom sub lens is the same with a cambering direction of the top sub-lens.

17. The manufacturing method of claim 9, further comprising:
forming a first planar layer above the bottom sub lenses, wherein the continuous microlens is formed on the first planar layer.

18. The manufacturing method of claim 9, further comprising:
forming a color filter layer above the bottom sub lenses.

19. The manufacturing method of claim 18, wherein the color filter layer directly contacts and covers a cambered surface of each of the bottom sub lenses.

20. The manufacturing method of claim 18, further comprising:
forming a second planar layer on the bottom sub lenses, wherein the color filter layer is formed on the second planar layer, and the second planar layer covers a cambered surface of each of the bottom sub lenses.
